(19) United States
(12) Patent Application Publication
(10) Pub. No.: US 2013/0263924 A1
(43) Pub. Date: Oct. 10, 2013

(54) Organic Solar Cell Comprising Self-Assembled Organic/Inorganic Nanocomposite in Photoactive Layer, and Method for Preparing the Same.

(71) Applicant: GWANGJU INSTITUTE OF SCIENCE AND TECHNOLOGY, Gwangju (KR)

(72) Inventors: Won Bae KIM, Gwangju (KR); Yong Seok KIM, Gwangju (KR)

(73) Assignee: GWANGJU INSTITUTE OF SCIENCE AND TECHNOLOGY, Gwangju (KR)

(21) Appl. No.: 13/712,078

(22) Filed: Dec. 12, 2012

(30) Foreign Application Priority Data
Apr. 6, 2012 (KR) 10-2012-0035905

(51) Int. Cl. H01L 51/42

(52) U.S. Cl. CPC H01L 51/4266
USPC 136/263; 438/82

(57) ABSTRACT

The present invention relates to an organic solar cell having an enhanced light efficiency by using an organic/inorganic nanocomposite in which a metal nanorod and an electron acceptor are self-assembled, in a photoactive layer, and a method of preparing the same. According to the present invention, since the metal nanorod and the electron acceptor are self-assembled, separated electrons are easily transported, and since electron transport via a metal is easier than that via an organic material, the electron transport speed via the metal nanorod of the present invention is faster than that via a related art organic material. Therefore, the organic solar cells of the present invention can increase the charge mobility within the photoactive layer to enhance the photoconversion efficiency.

### CROSS-REFERENCE TO RELATED APPLICATION

This application claims priority to Korean Patent Application No. 10-2012-0035905 filed on April 6, 2012 and all the benefits accruing therefrom under 35 U.S.C. §119, the contents of which are incorporated by reference in their entirety.

### BACKGROUND

The present invention disclosed herein relates to an organic solar cell including a self-assembled organic/inorganic nanocomposite in a photoactive layer, and a method of preparing the same, and more particularly, to an organic solar cell to enhance power conversion efficiency by using a nanocomposite in which a metal nanorod and an electron receptor are self-assembled, in a photoactive layer, and a method of preparing the same.

In recent years, as consumption of fossil fuels sharply increases, oil prices have been sharply increase, and environment issues such as global warming have also been raised. To this end, necessity of clean alternative energy has been elevated. Thus, most of countries devote all might to development of new regeneration energy sources, and with the effectuation of Kyoto Protocol, development of environmentally-friendly pollution free energy sources has been raised as an urgent problem of nations.

A solar cell technology producing electricity from light of the sun, a limitless energy source, is a field attracting the greatest interest among various new regeneration technologies. An inorganic silicon solar cell currently occupying a main portion of the solar cells has been commercialized and comes into the markets. The inorganic silicon solar cell, however, has a drawback, such as expensive material prices and limit of material supply. A complicated manufacturing process is also a cost rise factor.

Therefore, as an alternative of such an inorganic silicon solar cell, an organic solar cell attracts person's attention. An organic solar cell has advantages, such as superior processability, diversity and economic feasibility (inexpensive raw material) of organic materials. Also, the organic solar cell has an advantage in that the manufacturing process thereof is simple to thus decrease the manufacturing cost.

At the present, the organic solar cell further attracts people's attraction as a process technology for manufacturing a roll to roll process for formation of a large area thin film has been developed. For high efficiency of such organic solar cells, it is essential to improve a contact resistance in an interface between a photoactive layer and a metal electrode.

Currently, a bulk hetero junction structure that may effectively induce a charge separation via an optimized contact area of electron donors and electron acceptors is widely used as a photoactive layer. However, since the organic solar cells having such a structure use organic materials such as P3HT (electron donor) and PCBM (electron acceptor) having a low charge mobility (ca. 1×10⁻⁸ m²V⁻¹S⁻¹), charge transport within the organic solar cell is greatly limited, which has been pointed out to be a main reason in low photoconversion efficiency.

### SUMMARY

The present invention provides an organic solar cell to enhance the photoconversion efficiency by increasing the charge mobility within the organic solar cell, and a method of manufacturing the same.

The present invention also provides a method able to enhance the charge mobility within an organic solar cell.

In accordance with an exemplary embodiment of the present invention, a solar cell includes: a first electrode layer formed on a substrate; a photoactive layer formed on the first electrode layer, in which an organic/inorganic nanocomposite and electron donors are mixed; and a second electrode layer formed on the photoactive layer.

The organic/inorganic nanocomposite may be formed by bonding of an electron acceptor of an organic material and a metal nanorod, and the metal nanorods may be dispersed in the photoactive layer to provide an electron transport pathway transporting electrons to the second electrode layer.

In accordance with another exemplary embodiment of the present invention, a method of manufacturing an organic solar cell includes: forming a first electrode layer on a substrate; forming a photoactive layer on the first electrode layer; and forming a second electrode layer on the photoactive layer, wherein the forming of the photoactive layer is performed by mixing the organic/inorganic nanocomposite including the electron acceptor and the metal nanorod boned to each other with the electron donor and coating a mixture of the organic/inorganic nanocomposite and the electron donor on the first electrode layer.

### BRIEF DESCRIPTION OF THE DRAWINGS

Exemplary embodiments can be understood in more detail from the following description taken in conjunction with the accompanying drawings, in which:

FIG. 1 is a cross-sectional view of a solar cell according to an embodiment of the present invention;

FIG. 2 is a schematic view of an organic/inorganic composite formed by self-assembling of a metal nanorod and electron acceptors;

FIG. 3 shows (a) SEM pattern, (b) TEM pattern, (c) HRTEM pattern, and (d) XRD pattern of a manufactured metal nanorod;

FIG. 4 is a graph showing (a) variation in light absorption of a manufactured organic/inorganic nanocomposite, and (b) variation in light absorption when a metal nanorod is inserted simply in a photoactive layer;

FIG. 5 is a J-V graph in Examples 1 to 3 and Comparative Example 1 and 2;

FIG. 6 is a J-V graph in Example 2 and Comparative Example 3; and

FIG. 7 is a graph showing electron mobility measured using a space-charge limited current.

### DETAILED DESCRIPTION OF EMBODIMENTS

Hereinafter, preferred embodiments of the present invention will be described in detail with reference to the accompanying drawings. It should be understood that the following description is made to explain preferred embodiments of the present invention and the present invention is not necessarily limited thereto. In the figures, the thicknesses (or heights) of layers may be exaggerated for clarity of illustration as compared with other layers, and the meaning of exaggeration will be correctly understood in the light of concrete purports to be described later.

It should be understood that the stack structure mentioned in the specification description is exemplary and the present invention is not limited to such a specific structure.

In the specification, it will be understood that the term ‘on’ or ‘over’ may be used to mention a relative location relationship, another element or layer may be directly on the mentioned layer, or another layer (intermediate layer) or element may be intervened therebetween, or a layer may be disposed on a mentioned layer but may not complete cover a surface the mentioned layer (especially, having a stereoscopic shape). Therefore, unless the term ‘directly’ is separately used, the term ‘on’ or ‘over’ will be construed to be a relative concept. Similarly to this, it will be understood that the term ‘under’, ‘beneath’, or ‘below’ will be construed to be a relative concept.

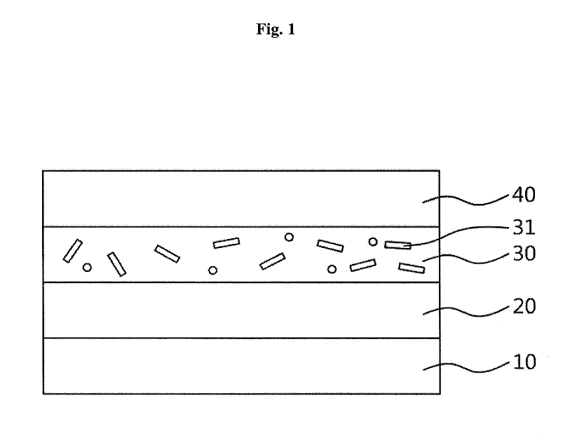

FIG. 1 is a cross-sectional view of a solar cell according to an embodiment of the present invention.

Referring to FIG. 1, an organic solar cell of the present invention includes a first electrode layer 20, a photoactive layer 30, and a second electrode layer 40.

The substrate 10 may be used without any limitation if it is made of a transparent material of glass, polycarbonate, polymethylmethacrylate, polyethyleneterephtalate, polyamide, polyethersulfone, or the like.

The first electrode 20 and the second electrode 40 are counter electrodes corresponding to each other, and if the first electrode is a positive electrode, the second electrode may be a negative electrode, and vice versa. Preferably, the first electrode 20 may be a positive electrode. The positive electrode may be coated with indium tin oxide (ITO), SnO₂, IZO (In₂O₃—ZnO), aluminum doped ZnO (AZO), gallium doped ZnO (GZO), or the like, preferably ITO. The first electrode layer 20 may be preferably formed by any one of well known methods, such as a sputtering, a vapor evaporation, or an ion beam evaporation.

The organic solar cell of present invention includes the photoactive layer 30 formed by mixing an organic/inorganic composite with electron donors.

The photoactive layer 30 is formed on the first electrode layer 20, and has a bulk hetero-junction structure in which electron acceptors and electron donors exist in a mixed state. The electron donor may be made of a conductive polymer, a low molecular semiconductor, or the like, and for example, may be made of a material selected from the group consisting of PPV (poly(para-phenylene vinylene)-based materials, polythiophene derivatives, and pthalocyanine-based materials. Concrete examples of a material constituting the electron donor may include polyaniline, polypyrrole, polythiophene, poly(p-phenylenevinylene), poly[2-methoxy-5-(2′-ethylhexyloxy)-1,4-phenylene vinylene (MEHPPV), poly(2-methoxy-5-(3,7-dimethyloctyloxy)-1,4-phenylenevinylene (DMOPPV), pentacene, poly(3,4-ethylenedioxythiophene) (PEDOT), poly(3-alkylthiophene), and particularly poly(3-hexylthiophene) (P3HT) is preferred.

The organic/inorganic nanocomposite is formed by bonding of electron acceptors of an organic material and metal nanorods, and the metal nanorods are dispersed in the photoactive layer to provide an electron transport pathway transporting electrons to the second electrode layer.

Referring to FIG. 1, the metal nanorods 31 are mixed in the form of an organic/inorganic composite within the photoactive layer 30.

Upon considering the characteristics of the bulk hetero-junction (BHJ) in which electron donors are mixed with electron acceptors to form a single layer, since electrons may be generated in any region of the photoactive layer, it is preferable that the metal nanorods functioning as an electron transport pathway are uniformly dispersed in the entire region of the photoactive layer.

The metal nanorods 31 include nanotubes, nanotrees, nanoribbons as well as nanorods, and nanowires having a nanosized diameter. The metal nanorods 31 may have a diameter ranging from 30 nm to 200 m and a length ranging from 150 nm to 2000 nm.

Also, the metal nanorods 31 may be used without any limitation if they are made of a conductive metal, preferably gold (Au), silver (Ag), platinum (Pt), copper (Cu), iron (Fe), titanium (Ti), tungsten (W), indium (In), aluminum (Al), any mixtures thereof, or any alloys thereof, more preferably Au. Besides metals, the metal nanorods 31 may be made of a conductive metal oxide, such as ITO (Sn-doped Indium Oxide) or the like.

The organic/inorganic nanocomposite may be formed by bonding of the metal nanorods and electron acceptors, i.e., organic material. The term “bonding” used herein means not a physical bonding that the metal nanorod is simply inserted or mixed in the photoactive layer, but a chemical bonding that the metal nanorod is chemically bonded with the electron acceptor to form a composite. An example of the chemical bonding may be a covalent bond between the metal nanorod and the electron acceptor, does not exclude a hydrogen bond, a bond by an electrostatic attraction, and the like, and may be comprehensively expressed as a chemical adsorption.

Since the organic/inorganic composite by covalent bonds is a composite having covalent bonds, it much easier to transport electrons from the electron acceptor to the metal nanorod.

Also, since it is much easier to transport electrons via the organic/inorganic composite of the present invention than to transport electrons via a related art inorganic structure, even when the content of the electron acceptors is decreased within 50%, the same photoconversion efficiency is exhibited. In case where the organic material of the electron acceptor has a sulfur group and the metal nanorod is made of Au, the organic material and the metal nanorod may be self-assembled to form a covalent bond. That is, the sulfur group easily reacts with Au in a solution to form a covalent bond.

Examples of the electron acceptor may include fullerenes, such as C₆₀, C₇₀, C₇₆, C₇₈, C₈₂, C₉₀, C₉₄, C₉₆, C₇₂₀, C₈₆₀, and the like; and fullerene derivatives such as 1-(3-methoxy-carbonyl)propyl-1-phenyl(6,6)C₆₁(1-(3-methoxy-carbonyl)propyl-1-phenyl(6,6)C₆₁:PCBM), C₇₁-PCBM, C₈₄-PCBM, bis-PCBM, and thienyl-C₆₁-butyricacidmethylester (ThCBM). Preferably, ThCBM having a sulfur group may be used.

It is noted that an embodiment of the present invention uses, as an electron acceptor, a fullerene derivative obtained by bonding a sulfur group to any of the foregoing fullerene derivatives. For example, a fullerene derivative including a sulfur group, such as thiol or thiophene may be used as an electron acceptor.

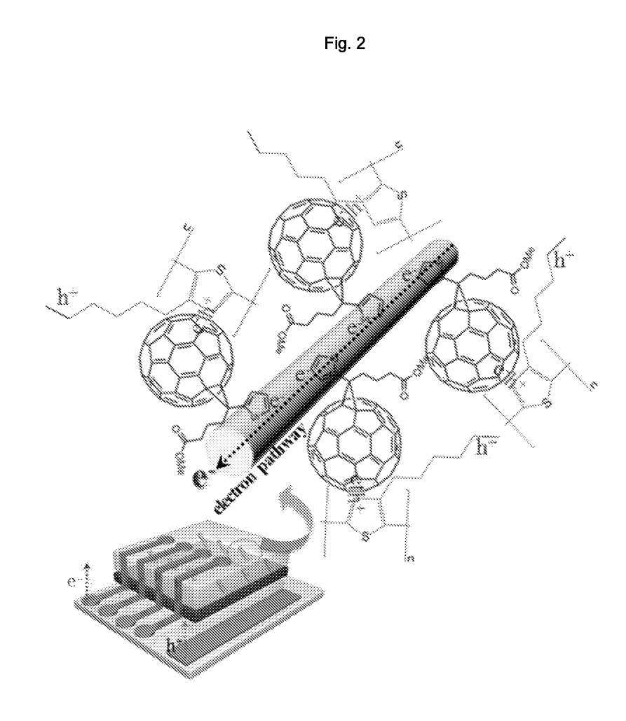

FIG. 2 is a schematic view of an organic/inorganic composite formed by self-assembling of a metal nanorod and electron acceptors having sulfur groups. Referring to FIG. 2, it is shown that the electron acceptors (ThCBM) having sulfur groups are covalently bonded along the (111) surface of a gold (Au) nanorod. That is, since the sulfur group at one end of the electron acceptor shares an electron with an Au atom, electrons which were generated in and separated from the electron donors may be easily transported from the electron acceptors to the metal nanorod. Also, since the conductive metal is easier in electron transport than the organic material, the transport speed of electrons to the electrode layer via the metal nanorod is faster than that via the related art organic material. Therefore, the organic solar cells of the present invention can increase the charge mobility within the organic solar cell to enhance the photoconversion efficiency.

The second electrode layer 40 may be made of a metal having a lower work function than a metal constituting the first electrode layer 20, and the second electrode layer 160 may be, for example, an Au, Al, Ca, Mg, Ba, Mo, Al—Mg or LiF—Al layer.

An organic solar cell of the present invention may include a hole transport layer between the first electrode layer 20 and the photoactive layer 30, and an electron transport layer between the photoactive layer 30 and the second electrode layer.

The hole transport layer may capture holes generated in the photoactive layer and transport the captured holes. The hole transport layer may be formed of a well known material. The hole transport layer may include, but be not limited to, for example, poly(3,4-ethylenedioxythiphene) (PEDOT), poly(styrenesulfonate) (PSS), polyaniline, phthalocyanine, pentacene, polydiphenyl, acetylene, poly(t-butyl)diphenylacetylene, poly(trifluoromethyl)diphenylacetylene, copper phthalocyanine (Cu-PC), poly(bistrifluoromethyl)acetylene, poly-bis(T-butyldiphenyl)acetylene, poly(trimethylsilyl)diphenylacetylene, poly(carbazole)diphenylacetylene, polydiacetylene, polyphenylacetylene, polypyridineacetylene, polymethoxyphenylacetylene, polymethylphenylacetylene, poly(t-butyl)phenylacetylene, polynitrophenylacetylene, poly(trifluoromethyl)phenylacetylene, poly(trimethylsilyl)phenyl acetylene, and combinations of two or more thereof.

Preferably, the hole transport layer may be formed of a mixture of poly(3,4-ethylenedioxythiophene (PEDOT) and poly(styrenesulfonate) (PSS).

A method of manufacturing an organic solar cell according to the present invention includes: forming a first electrode layer on a substrate; forming a photoactive layer on the first electrode layer by mixing an organic/inorganic composite in which an electron acceptor is bonded to a metal nanorod, with an electron donor; and forming a second electrode layer on the photoactive layer.

The forming of the first electrode layer or the forming of the second electrode layer may be performed by referring to the above-mentioned description or by using a well known method.

The forming of the photoactive layer is performed by mixing an organic/inorganic composite in which an electron acceptor is bonded to a metal nanorod, with an electron donor to obtain a mixture and coating the obtained mixture on the first electrode layer.

The organic/inorganic nanocomposite is prepared by mixing the electron acceptors and the metal nanorod in a solvent to self-assemble the electron acceptors and the metal nanorod for 12-36 hours, preferably for 12-24 hours.

The solvent may include chlrolobenzene, dichlorobenzene, chloroform, toluene, and the like.

In terms of the organic/inorganic nanocomposite, the electron acceptor, the electron donor, and the metal nanorod, the above-mentioned description may be referred. It is preferable that the electron receptor for forming the nanocomposite is thienyl-C₆₁-butyricacidmethylester and the metal nanorod is a gold nanorod.

A method of manufacturing an organic solar cell according to the present invention includes: adding electron donors to a prepared nanocomposite and mixing the nanocomposite and the electron donors to obtain a mixture solution; and coating the mixture solution on a first electrode layer.

In the method of the present invention, 0.2-0.002 pars by weight of a metal nanorod may be used with respect to 100 parts by weight of an electron donor, and 40-150 parts by weight, preferably 40-100 parts by weight, most preferably about 50 parts by weight of an electron acceptor may be used with respect to 100 parts by weight of an electron donor. According to the present invention, the content of the metal nanorod and the amount of the electron donor can be remarkably decreased, compared with those in the related art.

The coating of the mixture solution may be a spin coating, an ink jet printing, or a screen printing.

The present invention will be described in more detail with preferred examples, but the present invention is not limited only to these examples.

Synthesis of Metal Nanorod

A gold (Au) nanorod was synthesized by an electro deposition using a polycarbonate nanotemplate.

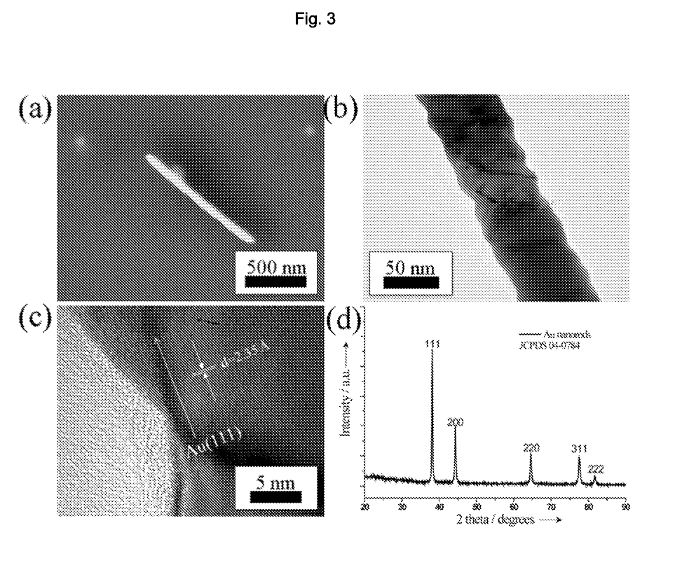

The gold nanorod had an average diameter of 50 nm and a length of about 1 μm. A SEM pattern, a TEM pattern, a HRTEM pattern, and an XRD pattern of the manufactured metal nanorod are shown in FIGS. 3(a) to 3(d).

Synthesis of Organic/Inorganic Nanocomposite

The gold nanorod (0.005 mg) manufactured previously was immersed in 1,2-dichlorobenzene (1 ml) and dispersed for 3 hours by using ultrasonic waves.

Afterwards, ThCBM (12 mg) was mixed with 1,2-dichlorobenzene in which the metal nanorods were well dispersed and then stirred for about 24 hours to prepare an organic/inorganic nanocomposite.

Next, P3HT (24 mg) was put in, mixed with 1,2-dichlorobenzene containing the organic/inorganic composite, and then stirred for a time period of not less than 24 hours to prepare a photoactive layer solution.

The photoactive layer solution was prepared such that the contents of the metal nanorods were 0.05 mg/ml, 0.005 mg/ml, and 0.0005 mg/ml with respect to the overall content of the photoactive layer solution.

### EXAMPLE 1

An ITO layer as a first electrode layer was deposited on a glass substrate and then treated by using oxygen plasma. PEDOT:PSS (Baytron Company) was spin-coated on the ITO layer to form a hole transport layer to a thickness of about 30 nm. Thereafter, the resultant substrate was thermally treated for 10 minutes at 150° C.

The photoactive layer solution prepared previously was spin-coated on the hole transport layer for 60 seconds at 700 rpm. Thereafter, a Ca buffer layer was formed on the photoactive layer to 20 nm, and then an aluminum (Al) layer as a second electrode layer was thermally deposited on the Ca buffer layer to 100 nm, thereby obtaining an organic solar cell.

### EXAMPLE 2

An organic solar cell was manufactured in the same manner as that in Example 1 except that the mass of the gold nanorod was 0.0005 mg/ml in the photoactive layer solution.

### EXAMPLE 3

An organic solar cell was manufactured in the same manner as that in Example 1 except that the mass of the gold nanorod was 0.05 mg/ml in the photoactive layer solution.

### COMPARATIVE EXAMPLE 1

### P3HT/ThCBM

An organic solar cell was manufactured except that the photoactive layer was manufactured by coating P3Ht/ThCBM (using the gold nanorod).

### COMPARATIVE EXAMPLE 2

### P3HT/ThCBM/Au NRs, Without Self-Assembly

An organic solar cell was manufactured except that the photoactive layer was manufactured by performing concurrent and direct mixing/coating in a solvent without forming an organic/inorganic composite.

### COMPARATIVE EXAMPLE 3

### P3HT/ThCBM-1:1

An organic solar cell was manufactured except that the content ratio of P3Ht/ThCBM was made to have 1:1 without using the gold nanorod.

It was confirmed that the metal nanorod was a gold nanorod from (a) SEM image, (b) TEM image, and (c) HRTEM image of FIG. 3, and it was known that the gold nanorod had a polycrystalline structure from (d) XRD pattern of FIG. 3.

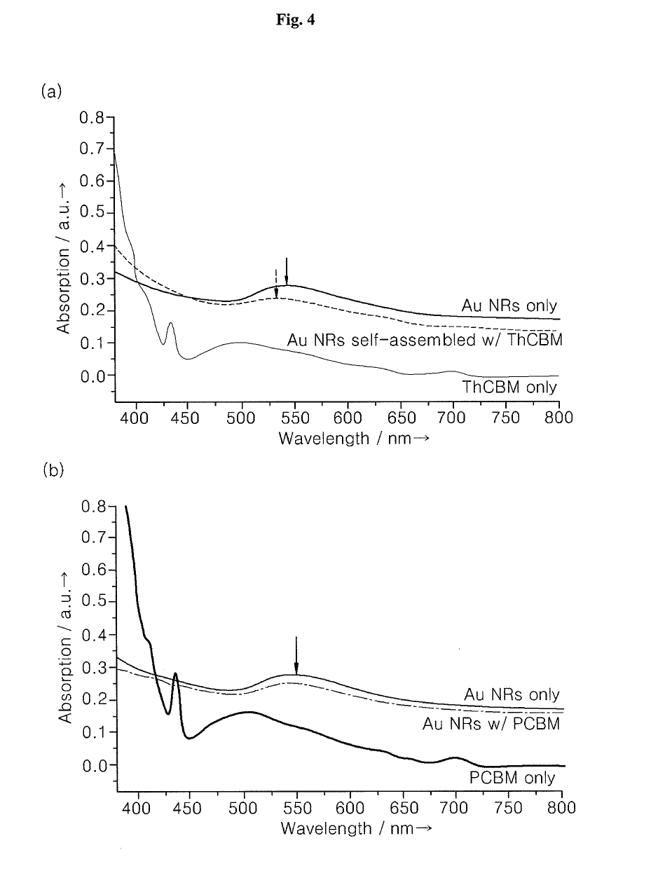

FIG. 4 is a graph showing (a) variation in light absorption of a manufactured organic/inorganic nanocomposite, and (b) variation in light absorption when a metal nanorod was inserted simply in a photoactive layer. As seen from FIG. 4(a), the plasmon band of the gold nanorod self-assembled with ThCBM was shift to a red wavelength of 532 nm, compared with 542 nm that was the wavelength of an inherent plasmon band of the gold nanorod. However, as seen from FIG. 4(b), when light absorption of a gold nanorod no having a sulfur group, which was subject to a self assembling was analyzed, the plasmon band of the gold nanorod was not shifted at all. Therefore, it was confirmed that an organic/inorganic composite was implemented by using a covalent bond of the gold nanorod and the sulfur group of ThCBM.

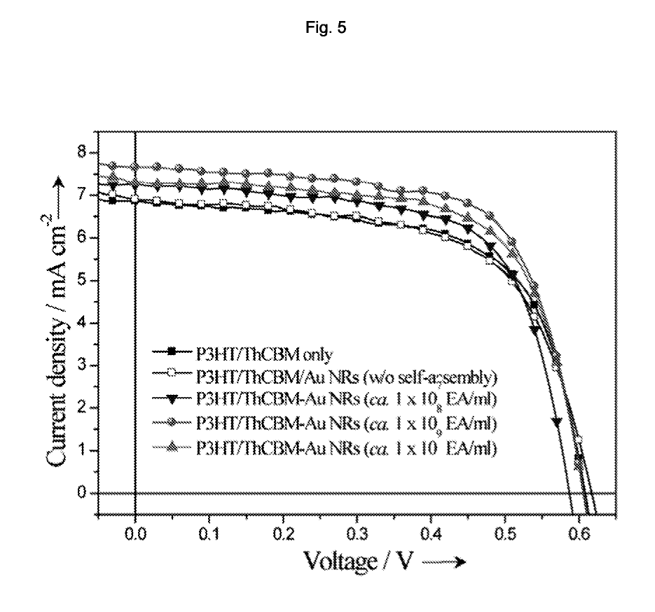

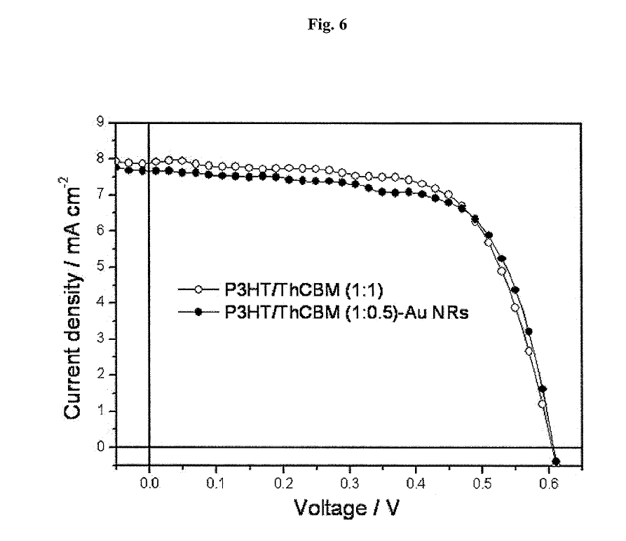

FIG. 5 is a J-V graph in Examples 1 to 3 and Comparative Example 1 and 2, and FIG. 6 is a J-V graph in Example 2 and Comparative Example 3.

Table 1 below shows measured values of the photoconversion factor in such examples.

TABLE 1

| Photoactive layers | JSC (mA/cm²) | VOC (V) | FF (%) | PCE (%) |
|---|---|---|---|---|
| Comparative Ex. 1 | 6.86 | 0.61 | 63.9 | 2.67 |
| Comparative Ex. 2 | 6.91 | 0.62 | 61.5 | 2.62 |
| Comparative Ex. 3 | 7.87 | 0.61 | 66.2 | 3.16 |
| Example 1 | 7.24 | 0.59 | 66.2 | 2.81 |
| Example 2 | 7.66 | 0.61 | 67.2 | 3.12 |
| Example 3 | 7.31 | 0.61 | 66.5 | 2.95 |

Referring to FIGS. 5 and 6, and Table 1, it was confirmed that the photoconversion efficiencies (PCE) in Examples 1 through 3 were more enhanced than those in Comparative Examples 1 and 2. Especially, the photoconversion efficiency (PCE) in Example 2 was enhanced by 17%, compared with those in Comparative Examples. Also, it was exhibited that although the amount of the electron acceptor in Example 2 was half of that in Comparative Example 3, the PCE in Example 2 was similar to that in Comparative Example 3.

Also, when the nanocomposite of the present invention was applied, the current density, the fill factor, and the like were enhanced.

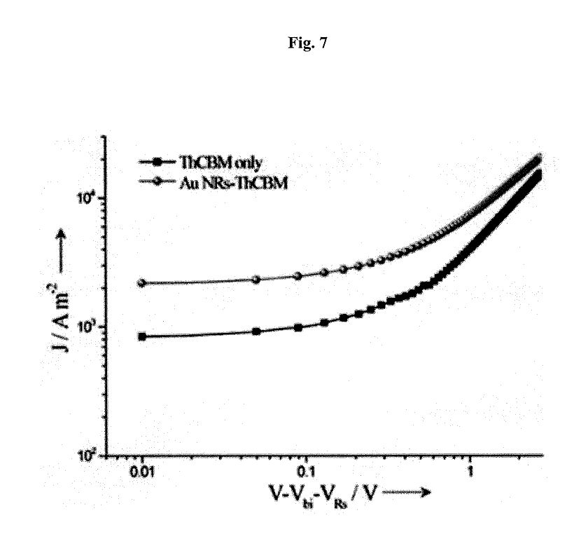

FIG. 7 is a graph showing the electron mobility measured using a space-charge limited current. Referring to FIG. 7, the electron mobility in Comparative Example 1 was 4.9×10⁻⁸ m² V⁻¹ S⁻¹, but that in Example 2 was 6.6×10⁻⁸ m² V⁻¹ S⁻¹, and was enhanced by about 35%.

According to the present invention, since the metal nanorod and the electron acceptor are self-assembled, separated electrons are easily transmitted to the metal nanorod, and since electron transport via a metal is easier than that via an organic material, the electron transport speed via the metal nanorod of the present invention is faster than that via a related art organic material. Therefore, the organic solar cells of the present invention can increase the charge mobility within the photoactive layer to enhance the photoconversion efficiency.

The organic solar cell according to the present invention can enhance the current density and fill factor.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

Description of Symbols

| | |
|---|---|
| 10: Substrate | 20: First electrode layer |
| 30: Photoactive layer | 40: Second electrode |
| 41: Metal nanorod | |

What is claimed is:

1. An organic solar cell comprising:
a first electrode layer formed on a substrate;
a photoactive layer formed on the first electrode layer, in which an organic/inorganic nanocomposite and electron donors are mixed; and
a second electrode layer formed on the photoactive layer.
wherein the organic/inorganic nanocomposite may be formed by bonding of an electron acceptor of an organic material and a metal nanorod, and the metal nanorods may be dispersed in the photoactive layer to provide an electron transport pathway transporting electrons to the second electrode layer.

2. The organic solar cell of claim 1, wherein the electron acceptor has a sulfur group, and is self-assembled with the metal nanorod.

3. The organic solar cell of claim 1, wherein the metal nanorod is made of at least one selected from gold (Au), silver (Ag), platinum (Pt), copper (Cu), iron (Fe), titanium (Ti), tungsten (W), indium (In), aluminum (Al), any mixtures thereof, or any alloys thereof.

4. The organic solar cell of claim 1, wherein the electron acceptor is ThCBM (thienyl-C₆₁-butyricacidmethylester), and the metal nanorod is a gold nanorod.

5. The organic solar cell of claim 1, wherein the metal nanorod has a diameter ranging from 30 nm to 200 nm and a length ranging from 150 nm to 2000 nm.

6. A method of manufacturing an organic solar cell, the method comprising
forming a first electrode layer on a substrate;
forming a photoactive layer on the first electrode layer; and
forming a second electrode layer on the photoactive layer,
wherein the forming of the photoactive layer is performed by mixing the organic/inorganic nanocomposite including the electron acceptor and the metal nanorod boned to each other with the electron donor and coating a mixture of the organic/inorganic nanocomposite and the electron donor on the first electrode layer.

7. The method of claim 6, wherein the forming of the photoactive layer comprises:
mixing the electron acceptor and the metal nanorod in a solvent and performing a self-assembling reaction for 12-36 hours to form a nanocomposite;
putting the electron donor in the nanocomposite and mixing the electron donor and the nanocomposite to prepare a mixture solution; and
coating the mixture solution on the first electrode layer.

8. The method of claim 7, wherein 0.002-0.2 parts by weight of the metal nanorod and 40-100 parts by weight of the electron acceptor are used with respect to 100 parts by weight of the electron donor.

9. The method of claim 6, wherein the electron acceptor is ThCBM (thienyl-C₆₁-butyricacidmethylester), and the metal nanorod is a gold nanorod.
